(19) United States
(12) Patent Application Publication
(10) Pub. No.: US 2011/0063915 A1
(43) Pub. Date: Mar. 17, 2011

(54) NON-VOLATILE SEMICONDUCTOR MEMORY DEVICE

(75) Inventors: Rieko TANAKA, Kanagawa-ken (JP); Takumi Abe, San Jose, CA (US)

(73) Assignee: KABUSHIKI KAISHA TOSHIBA, Tokyo (JP)

(21) Appl. No.: 12/723,960

(22) Filed: Mar. 15, 2010

(30) Foreign Application Priority Data
Sep. 16, 2009 (JP) 2009-213987

(51) Int. Cl. G11C 16/04; G11C 16/06; G11C 7/00

(52) U.S. Cl. 365/185.17; 365/185.22; 365/205

(57) ABSTRACT

A non-volatile semiconductor memory device includes a memory cell array having a plurality of non-volatile memory cells capable electrically rewriting data, bit lines and source lines. A driver circuit is coupled with the source lines of the memory cell array to output a voltage higher than a power source voltage or a programming voltage for writing data in the memory cell by switching over, and the driver circuit discharges the source lines to ground. A sense amplifier circuit is coupled with the bit line and reads out the data in the memory cell. The sense amplifier includes a sense node and a capacitor having first and second terminals, and the first terminal is coupled with the sense node. The sense node is boosted by a plurality of voltages applied to the second terminal of the capacitor.

### CROSS-REFERENCE TO RELATED APPLICATION

This application is based upon and claims the benefit of priority from prior Japanese Patent Application No. 2009-213987, filed Sep. 16, 2009, the entire contents of which are incorporated herein by reference.

### BACKGROUND OF THE INVENTION

1. Field of the Invention

The invention relates to a non-volatile semiconductor memory device, and more particularly to a non-volatile semiconductor memory device that has an erase verification function during writing operation.

2. Description of the Related Art

A NAND-type flash memory, which is one of non-volatile semiconductor memory devices, erases data in units of blocks including a plurality of memory cell transistors, and therefore requires verification reading operation (erase verification) for confirming whether the NAND-type flash memory obtains an erase state within a certain range of threshold voltage.

Conventionally, for example, Japanese Patent Application Laid-Open No. 2005-116102 suggests a method of performing erase verification on a NAND-type flash memory by using an ordinary sense amplifier circuit to determine variation of a bit line voltage. In view of a requirement for a lower power-supply voltage (Vdd), the sense amplifier circuit is arranged with a boosting capacitor in a sense node. The boosting capacitor ensures a large erase verification margin even in a lower power-supply voltage.

In the NAND-type flash memory, the size of memory cell transistors become extremely small, which causes variation in the threshold voltage of the memory cell transistors due to proximity effects between the adjacent memory cells. Even if the threshold voltage of the memory cell transistor in the erase state increases due to such a variation of the threshold voltage, the increased threshold voltage in the erase state still needs to be smaller than 0V. Therefore, when a block is erased, the target threshold voltage needs to be a still smaller value (deep erase). Accordingly, the reference value of the erase verification (erase verification voltage) needs to be still smaller.

According to the method disclosed in Japanese Patent Application Laid-Open No. 2005-116102, however, the reference value of the erase verification cannot be smaller than −Vdd, which poses a problem in achieving deep erase in view of the adjacency effects.

### BRIEF SUMMARY OF THE INVENTION

According to one aspect of the invention, there is provided a non-volatile semiconductor memory device including: a memory cell array having a plurality of non-volatile memory cells capable electrically rewriting data, bit lines and source lines; a driver circuit coupled with the source lines of the memory cell array, to output a voltage higher than a power source voltage or a programming voltage for writing data in a memory cell at an output terminal and discharge the source lines to ground by switching over; and a sense amplifier circuit coupled with the bit line to read data in the memory cell, the sense amplifier circuit including a sense node and a capacitor having a first terminal coupled with the sense node and a second terminal to receive a plurality of voltages to boost the sense node.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing a NAND-type flash memory according to an embodiment of the invention,

FIG. 2 is an equivalent circuit diagram showing a memory cell of the NAND-type flash memory according to the embodiment of the invention,

FIG. 3 is a circuit diagram of an erase verification operation in the NAND-type flash memory according to the embodiment of the invention,

FIG. 4 is a driver circuit diagram for providing a voltage of Vdd or more to a source line of the NAND-type flash memory according to the embodiment of the invention,

FIG. 5 is a ΔVclk generation circuit diagram of the NAND-type flash memory according to the embodiment of the invention,

FIG. 6 is a conceptual diagram showing erase verification operation of a memory cell transistor of the NAND-type flash memory according to the embodiment of the invention,

FIG. 7 is a conceptual diagram showing erase verification operation of a memory cell transistor of a NAND-type flash memory according to a comparative example,

FIG. 8 is a timing chart showing erase verification operation of the NAND-type flash memory according to the embodiment of the invention,

FIG. 9 is a timing chart showing time change of potentials at a clock node (CLK) and sense node (SEN) in erase verification operation of the NAND-type flash memory according to the embodiment of the invention,

FIG. 10 is a ΔVclk generation circuit diagram used in the NAND-type flash memory according to a comparative example, and

FIG. 11 is a timing chart showing time change of potentials at a clock node (CLK) and sense node (SEN) in erase verification operation of the NAND-type flash memory according to a comparative example.

### DETAILED DESCRIPTION OF THE INVENTION

A non-volatile semiconductor memory device according to an exemplary embodiment of the present invention will now be described with reference to the accompanying drawings wherein the same or like reference numerals designate the same or corresponding parts throughout the several view.

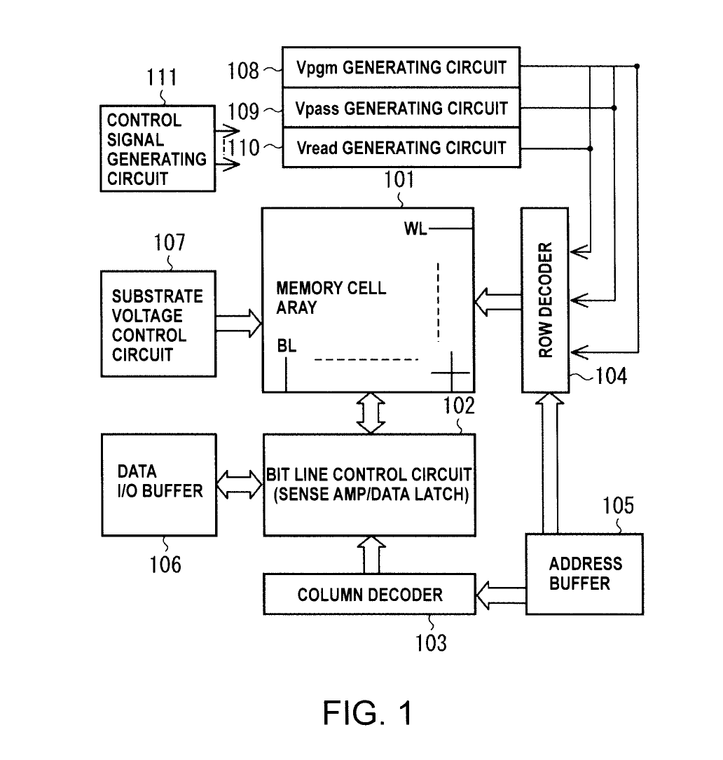

FIG. 1 shows a block diagram of non-volatile semiconductor memory device (for example, NAND-type flash memory) according to an embodiment of the invention. The NAND-type flash memory according to the present embodiment includes a memory cell array 101, a bit line control circuit (sense amplifier/data latch) 102, a column decoder 103, a row decoder 104, an address buffer 105, a data input/output buffer 106, a substrate voltage control circuit 107, a Vpgm generating circuit 108, a Vpass generating circuit 109, a Vread generating circuit 110, and a control signal generation circuit 111.

As described later, a memory cell array 101 is arranged with NAND strings each of which including non-volatile memory cells connected in series.

The bit line control circuit 102 is arranged to sense bit line data of the memory cell array 101 or maintain written data. The circuit performs bit line potential control in verification reading after data writing process and rewriting into an insufficiently written memory cell, and is mainly constituted by, for example, a CMOS flip flop.

The bit line control circuit 102 is coupled with the data input/output buffer 106. A connection between the bit line control circuit 102 and the data input/output buffer 106 is controlled by an output from the column decoder 103 that receives an address signal from the address buffer 105.

The row decoder 104 is arranged to select a memory cell in the memory cell array 101. More specifically, the row decoder 104 is arranged to control a control gate and a selection gate.

The writing voltage (Vpgm) generating circuit 108 is arranged to generate the writing voltage Vpgm boosted from the power supply voltage, when data are written into a selected memory cell of the memory cell array 101. In addition to the Vpgm generating circuit 108, the writing intermediate voltage (Vpass) generating circuit 109 and the reading intermediate voltage (Vread) generating circuit 110 are arranged. The writing intermediate voltage (Vpass) generating circuit 109 generates a writing intermediate voltage Vpass given to a non-selected memory cell during data writing operation. The reading intermediate voltage (Vread) generating circuit 110 generates a reading intermediate voltage Vread given to a non-selected memory cell during data reading operation (including verification reading operation).

The writing intermediate voltage Vpass and the reading intermediate voltage Vread are lower than the writing voltage Vpgm but are voltages boosted from a power supply voltage Vdd. The control signal generating circuit 111 controls, e.g., writing operation, erase operation, reading operation, writing verification operation, excessive writing verification operation, data erase operation for a unit of data latch, and writing operation for varying and setting an initial voltage of the writing operation and a voltage pulse equivalent to step-up.

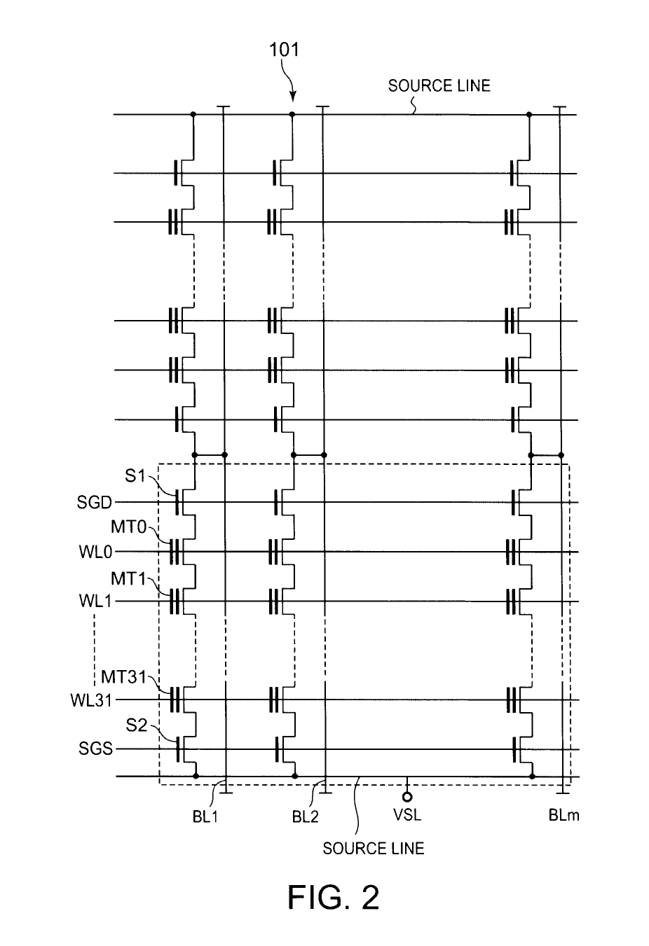

FIG. 2 is an equivalent circuit of the memory cell array 101. A plurality of memory cell transistors (M0 to M31) are connected in series in the column direction, and selection transistors (S1, S2) are coupled with both ends thereof, to structure a NAND string. In many cases, the number of the memory cell transistors (M0 to M31) coupled with one NAND string is generally 2^{k} (where k is a natural number) or 2^{k}+2, but the number of the memory cell transistors may be any number. In FIG. 2, thirty-two memory cell transistors are shown as an example. Between a plurality of NAND strings arranged in the row direction, the memory cell transistors M0 to M31 are commonly connected by word lines (WL0, WL1, . . . , WL31). Between the plurality of NAND strings arranged in the row direction, the selection transistors (S1, S2) are commonly connected by a drain side selection gate line SGD and a source side selection gate line SGS, in the same manner as the memory cell transistor M0 to M31. One end of each of the NAND strings is coupled with the bit lines (BL1 to BLm), and the other end is coupled with the source line SL.

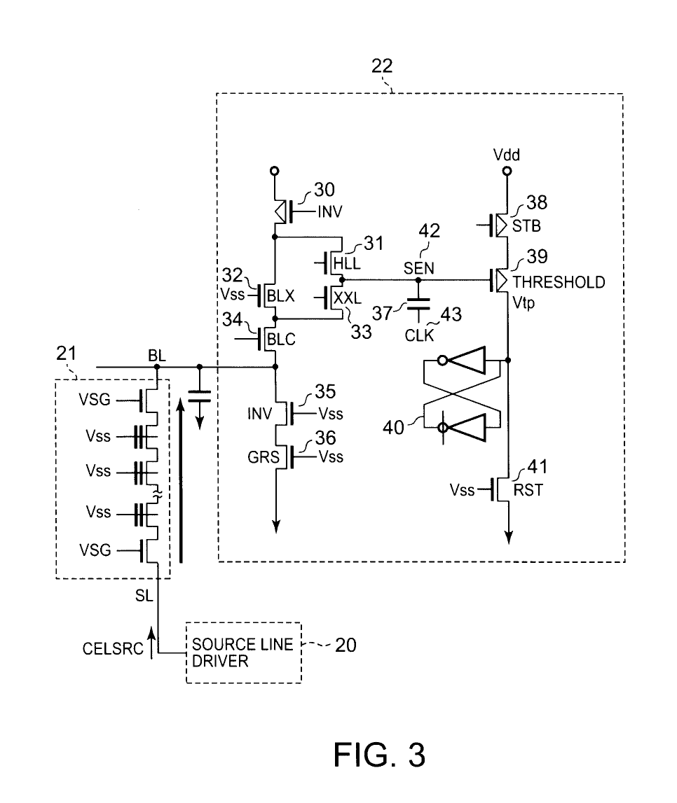

FIG. 3 is conceptual diagram showing a source line driver 20, a NAND string 21, and a sense amplifier circuit 22 according to the embodiment of the invention.

The source line driver 20 is coupled with a source side selection transistor S2 of the NAND string 21 via the source line SL. A drain side selection transistor S1 on the other end of the NAND string 21 is coupled with a sense node 42 (SEN) via a bit line BL, a bit line clamp transistor 34 (BLC), and an XXL transistor 33. The sense node 42 (SEN) is coupled with one terminal of a boost/step-down capacitor 37 for increasing a sense margin. The other terminal of the boost/step-down capacitor 37 is called a clock node 43 (CLK). The terminal of the XXL transistor 33 opposite to the terminal coupled with the bit line clamp transistor 34 (BLC) is coupled with an inverter transistor 30 (INV) via an HLL transistor 31 for charging the sense node 42 (SEN). The end of the sense node 42 (SEN) opposite to the XXL transistor 33 is coupled with the gate of a PMOS transistor 39 whose threshold voltage is Vtp. A source of the PMOS transistor 39 is coupled with a data latch circuit 40.

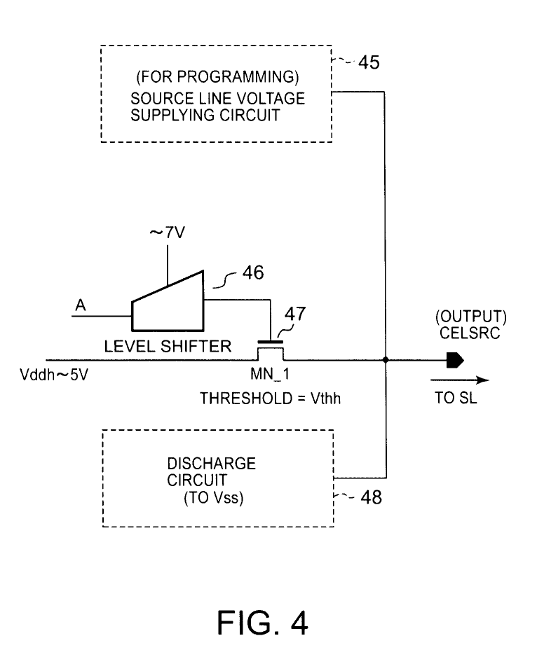

FIG. 4 shows a circuit diagram of the source line driver 20 shown in FIG. 3. A level shifter 46 is coupled with a power supply voltage of about 7 V and an external signal A which attains “H” during erase verification operation. The output from the level shifter 46 is coupled with the gate of a high-breakdown voltage NMOS transistor 47 (MN_1). The drain of the transistor 47 is coupled with Vddh of about 5 V. The transistor 47, a source line voltage supplying circuit 45 (for programming), and a discharge circuit 48 to Vss are coupled with the source line SL, and can be switched as an output voltage CELSRC from the source line driver 20.

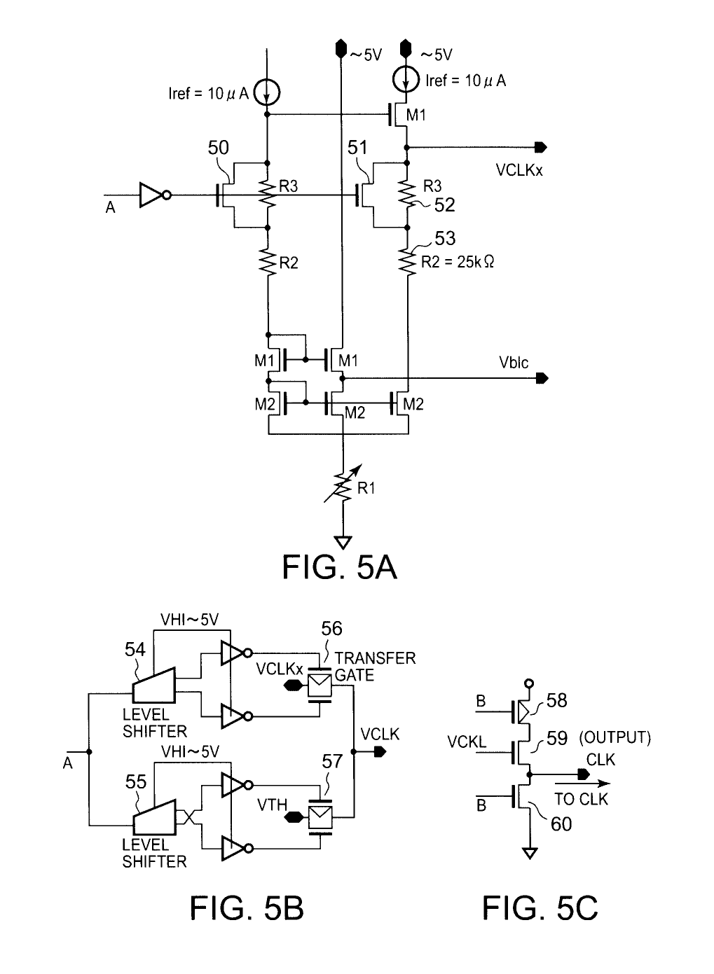

FIG. 5 shows a clock voltage CLK generating circuit applying the voltage of clock CLK to the clock node 43 (CLK) illustrated in FIG. 3. In the circuit shown in FIG. 5A, an input signal A is coupled with the gate of a NMOS transistor 51 via an inverter gate. The NMOS transistor 51 is arranged in parallel with a resistor 52 (R3). A resistor 53 (R2) is arranged in series with the NMOS transistor 51 and the resistor 52 (R3). A voltage represented by Iref×R2 or Irefx×(R2+R3) is output to a clock node (VCLKx) according to the input signal A. The VCLKx is inputted to a circuit shown in FIG. 5B. When the input signal A of FIG. 5B attains “H”, the VCLKx is transmitted to the clock node (VCLK) via a transfer gate 56. The VCLK is inputted to the circuit of FIG. 5C. When an input signal B of FIG. 5C attains “L”, the VCLK is transmitted to the clock node (CLK). When the threshold voltage of a NMOS transistor 59 of FIG. 5C is set to be Vtn, a voltage ΔVclk outputted to the clock node (CLK) is represented as ΔVclk=VCLKx−Vtn.

[Source Line Driver Operation]

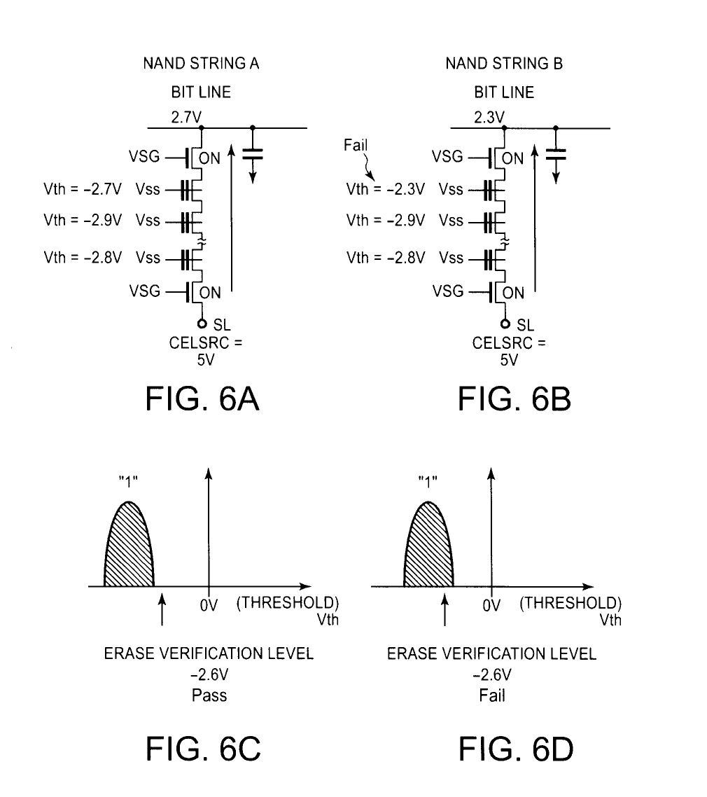

Subsequently, operation method of the source line driver 2 illustrated in FIG. 3 will be described referring FIGS. 4 and 6.

First, erase verification operation will be described. The following method for flowing a current from the source line SL of the NAND string to the bit line BL is used to perform erase verification operation of the NAND-type flash memory.

FIG. 6 is a conceptual diagram showing erase verification operation that is performed when the voltage CELSRC (5V) is applied to the source line SL. The erase verification level is set to be −2.6 V, whose absolute value is larger than Vdd (2.5 V). FIG. 6A shows erase verification operation performed on a NAND string A in a state of “pass” in which each memory cell transistor is erased to an extent below the erase verification level. FIG. 6C is a conceptual diagram showing a distribution of the threshold voltage of the memory cell transistor in that case. FIG. 6B shows erase verification operation performed on a NAND string B in a state of “fail” including a memory cell transistor that is not erased to the erase verification level. FIG. 6D is a conceptual diagram showing a distribution of the threshold voltage of the memory cell transistor in that case.

The bit line BL is discharged to 0V. The gate voltage Vg of each memory cell transistor included in a selected NAND string is set to Vss (0V). The gate voltage of the selected gate transistor is set to VSG, which is approximately a voltage which transfers the voltage CELSRC (about 5 V).

The voltage CELSRC (about 5 V) is applied to the source line.

In the example, the voltage CELSRC is an output from the source line driver 20 shown in FIG. 3 to the source line SL. During the erase verification, the external signal A shown in FIG. 4 attains “H”, and the output from the level shifter 46 attains about 7 V, which is about the power supply voltage of the level shifter 46. The output from the level shifter 46 is applied to the gate of the high-breakdown voltage NMOS transistor 47 (MN_1). The gate voltage of the NMOS transistor 47 is larger than a summation of the drain voltage Vddh (about 5 V) of the NMOS transistor 47 and the threshold voltage Vthh (about 1 V) of the NMOS transistor 47. Accordingly, even when a drop of the threshold voltage equivalent to Vthh is considered, the output voltage CELSRC from the source line driver 20 shown in FIG. 4 to the source line is the drain voltage Vddh (about 5 V) of the NMOS transistor 47.

In a case where the value of the voltage CELSRC is larger than the absolute value of the largest one of after-erase threshold voltage voltages of the memory cell transistors in the NAND string, the bit line voltage Vbl becomes the same as the absolute value of the largest one of after-erase threshold voltages Vth of the memory cell transistors in the NAND string due to the relationship of Vbl=Vg−Vth. For example, in the NAND string A shown in FIG. 6A, Vbl is 2.7 V. In the NAND string B shown in FIG. 6B, Vbl is 2.3 V.

When the level of the bit line voltage Vbl is detected by the sense amplifier, erase state of the NAND string can be confirmed. In other words, when the bit line voltage Vbl is larger than the absolute value of the erase verification reference value, the erase state is determined to be “pass” (erase completed). When the bit line voltage Vbl is determined to be smaller, the erase state is determined to be “fail” (incomplete erase). When the erase verification reference value is 2.6 V, the NAND string A shown in FIG. 6A is determined to be “pass”, and the NAND string B shown in FIG. 6B is determined to be “fail”.

### Comparative Example

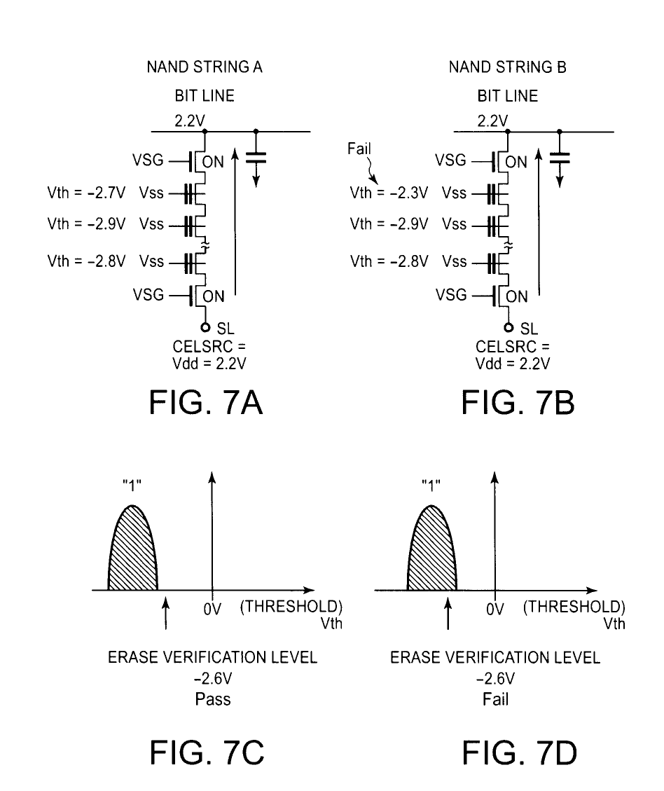

A comparative example of erase verification operation will be described with reference to FIG. 7. In the comparative example, the erase verification operation is performed when Vdd (2.2V, which is set in view of the variation of 10% with respect to the power supply voltage of 2.5 V) is applied to the source line during erase verification operation. The erase verification method of the present comparative example has a problem in that the reference value of the erase verification cannot be set to −Vdd or less as described below.

FIG. 7 is a conceptual diagram showing the erase verification operation performed when Vdd of 2.2 V is applied to the source line SL. The erase verification level is set to −2.6 V, whose absolute value is larger than Vdd (2.2 V). FIG. 7A shows erase verification operation performed on the NAND string A in a state of “pass” in which each memory cell transistor is erased to an extent below the erase verification level. FIG. 7C is a conceptual diagram showing a distribution of the threshold voltage of the memory cell transistor in that case. FIG. 7B shows erase verification operation performed on the NAND string B in a state of “fail” including a memory cell transistor that is not erased to the erase verification level. FIG. 7D is a conceptual diagram showing a distribution of the threshold voltage of the memory cell transistor in that case.

The bit line BL is discharged to 0V. The voltage Vg of each memory cell transistor included in a target NAND string is set to Vss (0V). The gate voltage of the selected gate transistor is set to VSG. The voltage Vdd (about 2.2 V) is applied to the source line.

However, the present comparative example is different from the case shown in FIG. 6 in that the source line potential Vdd is not larger than the absolute value of the largest one of after-erase threshold voltage voltages of the memory cell transistors in the NAND string. Therefore, the bit line voltage Vbl is the same as the source line potential Vdd in not only the NAND string A in the state of “pass” shown in FIG. 7A but also the NAND string B in the state of “fail” shown in FIG. 7B.

Therefore, whether the memory cell transistor has been erased to the reference value of the erase verification cannot be determined from the bit line potential Vbl. Since whether the erase verification is either “pass” or “fail” cannot be determined from the bit line potential Vbl, it is impossible to set the reference value of the erase verification to −Vdd or less in the comparative example.

In contrast, according to the source line driver 20 of the embodiment of the invention, the voltage CELSRC of about 5 V is inputted to the source line SL during erase verification operation. Therefore, as described above, whether the erase verification is either “pass” or “fail” can be determined from the bit line potential Vbl.

### [Sense Amplifier Operation]

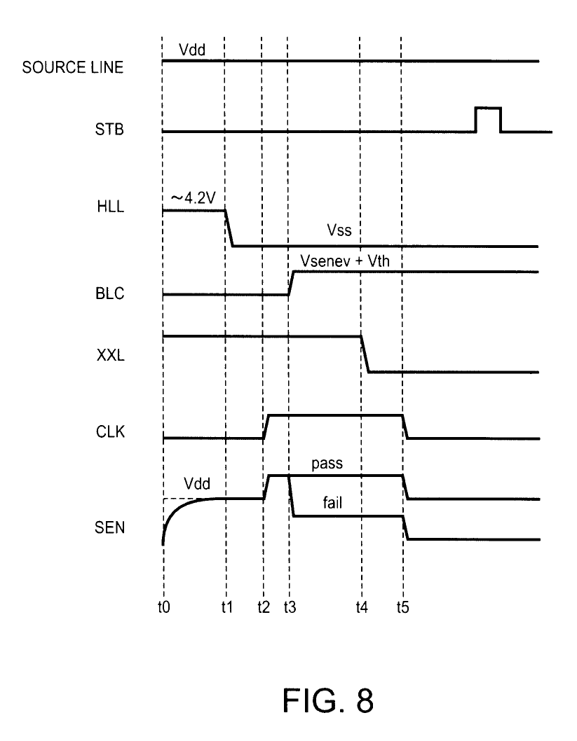

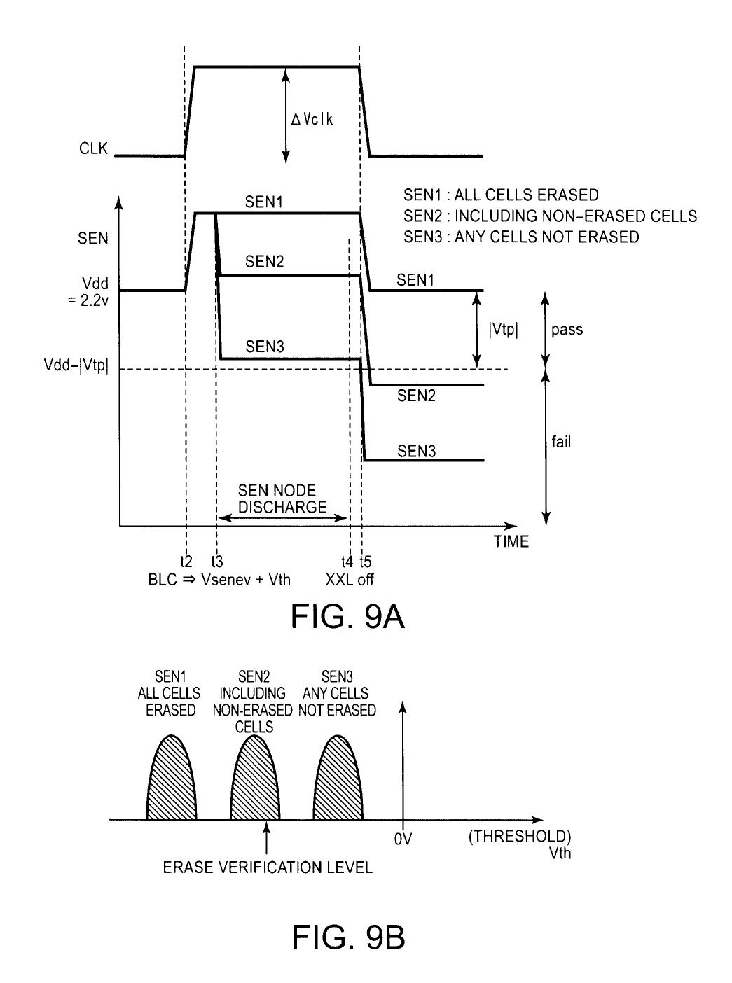

Subsequently, a method for increasing a sense margin of the erase verification operation in the embodiment of the invention will be described with reference to FIGS. 8 and 9.

FIG. 8 is a timing chart of the erase verification operation. First, basic operation of the erase verification will be described with reference to the timing chart shown in FIG. 8 with reference to the circuit diagram of the sense amplifier circuit 22 shown in FIG. 3.

At a time t0, the HLL transistor 31 shown in FIG. 3 is turned on, so that the sense node 42 (SEN) is charged to Vdd. Thereafter, at a time t1, the HLL transistor 31 is turned off, so that the charging path for the sense node 42 (SEN) is cut off. Subsequently, at time t2, the clock node 43 (CLK) shown in FIG. 3 is boosted by a particular voltage amount (ΔVclk). The sense node 42 (SEN) opposite to the clock node 43 (CLK) is further boosted from Vdd.

Subsequently, at a time t3, Vsenev+Vth is applied to the gate of the transistor 34 (BLC) shown in FIG. 3. In the present example, Vsenev is the absolute value of the reference value of the erase verification, and Vth is the threshold voltage of the transistor 34 (BLC). During the period up to a time t4, the XXL transistor 33 shown in FIG. 3 is in an ON state, and the discharge path of the sense node 42 (SEN) is ensured.

When the bit line level Vbl is higher than Vsenev, namely, when all of the memory cell transistors in the NAND string coupled withcoupled with the bit line are erased to a level below the reference value of the erase verification, the transistor 34 (BLC) turns off, so that the sense node 42 (SEN) has a potential boosted to Vdd or more (the potential of “pass” in FIG. 8).

In contrast, when there is any memory cell transistor that is not erased to a level below the reference value of the erase verification, the bit line potential Vbl is less than Vsenev, and accordingly, the transistor 34 (BLC) turns on. Therefore, due to charge transfer, the sense node 34 is discharged to approximately the same potential as the bit line potential Vbl (the potential of “fail” in FIG. 8).

Subsequently, at the time t4, the XXL transistor 33 shown in FIG. 3 is turned off. Accordingly, the discharge path for the sense node 42 (SEN) is cut off.

Subsequently, at a time t5, the clock node 43 (CLK) is stepped down. Accordingly, the sense node 42 (SEN) is also stepped down by approximately an amplitude (ΔVclk) of the clock CLK.

As described above, whether the erase verification operation is either “pass” or “fail” is determined based on whether the sense node 42 (SEN) is discharged or not at the time t3 or later.

Subsequently, the determination method of the potential at the sense node 42 (SEN) using the sense amplifier circuit 22 (method for determining whether the erase verification operation is either “pass” or “fail”) will be further described using FIG. 9.

FIG. 9A shows a timing chart extracted from the timing chart of FIG. 8 to enlarge a portion from the times t2 to t5 of the potential of the sense node 42 (SEN) and the clock node 43 (CLK). FIG. 9B is a schematic diagram showing a distribution of the threshold voltage of the memory cell transistor after erase. FIG. 9B corresponds to three cases (SEN1 to SEN3) of time change of the potential at the sense node (SEN) shown in FIG. 9A.

As described above, whether the erase verification operation is either “pass” or “fail” is determined based on whether the sense node (SEN) charged to Vdd is discharged or not. A value called trip point is used as a reference potential of the determination. The trip point is a gate voltage in a case where the PMOS transistor 39 of FIG. 3 performs switching. When Vdd is applied to a terminal on the upper right section of FIG. 3, the threshold voltage of the PMOS transistor 39 is Vtp, and the trip point is represented by the expression Vdd−|Vtp|.

Normally, the threshold voltage Vtp of the PMOS transistor 39 is set so that the trip point is equal to a value obtained by subtracting ΔVclk from the absolute value of the reference potential of the erase verification operation ΔVclk. However, when the power supply voltage Vdd and the threshold voltage Vtp vary, the reference potential of the erase verification may not necessarily be the same as the value of the trip point. Further, since there is a demand to lower the power supply voltage Vdd, the sense margin with respect to the above false reading operation tends to decrease.

A case such as when the reference potential of the erase verification is deeper than −Vdd, for example, the maximum value of the distribution of the threshold voltage of the after-erase memory cell transistor is larger than the reference potential of the erase verification and is less than −Vdd as shown in the distribution of SEN2 of FIG. 9B will be described. In such an occasion, the determination result of the erase verification needs to be “fail”. When the source line driver circuit shown in FIG. 4 is used, the bit line potential Vbl becomes the absolute value of the maximum value of the threshold voltage distribution SEN2 of the memory cell transistors. In this case, the sense node (SEN) has a potential of the power supply voltage (Vdd) or more, even after Vsenev+Vth is applied to the gate electrode of the transistor 34 (BLC) at the time t3 and the sense node 42 (SEN) is discharged to the bit line potential (BL). In order to step down this sense node (SEN) to the trip point or less at the time t5, the amplitude ΔVclk of the clock CLK needs to be about 2 V.

In this embodiment, with the clock VCLKx generating circuit as shown in FIG. 5, ΔVclk larger than that in a comparative example to be described later can be generated. When the input signal A of FIG. 5 attains “H”, a voltage represented by Irefx×(R2+R3) is outputted to the clock node (VCLKx). At this occasion, where Iref is 10 uA, R2 is about 25 kΩ, and R3 is 100 kΩ, the clock VCLKx becomes about 3.5 V. When the threshold voltage Vtn of the NMOS transistor 59 is about 1.5 V, ΔVclk=VCLKx−Vtn=2V holds. With the use of this ΔVclk, the potential of the sense node 42 (SEN) becomes the trip point value or less at the time t5, so that the erase verification result can be correctly determined to be “fail”.

### Comparative Example

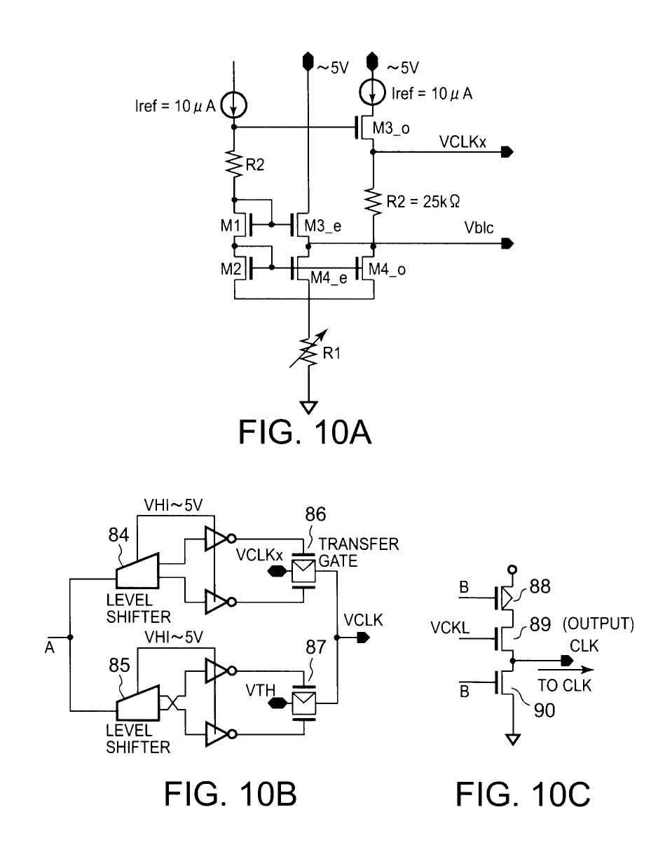

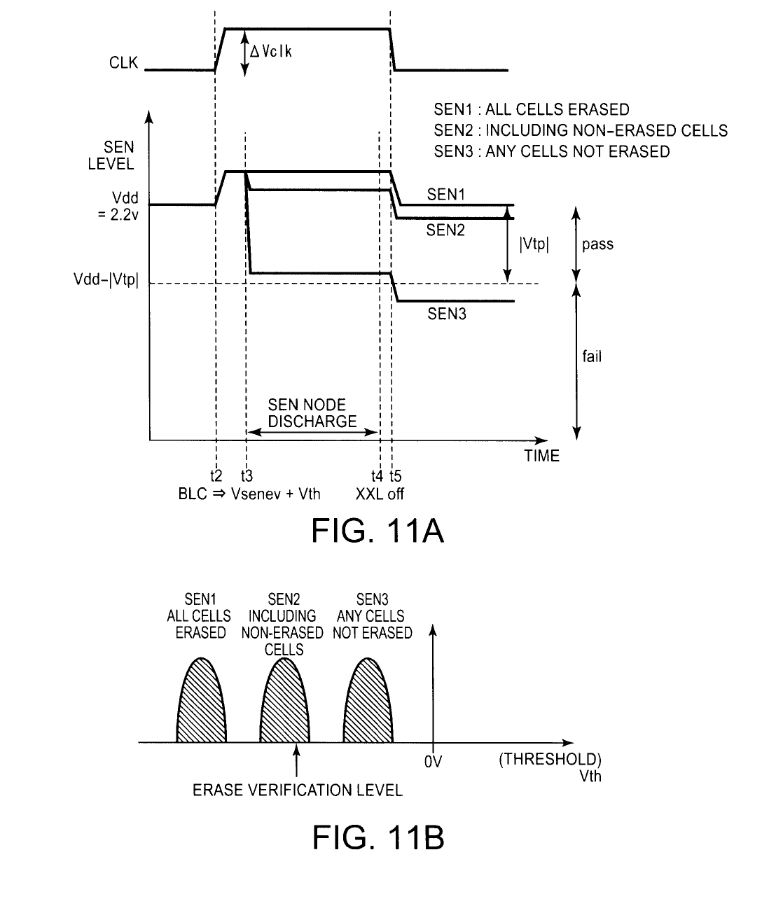

In the comparative example, such cases as when the reference potential of the erase verification is deeper than −Vdd, the result of the erase verification operation may be incorrectly read as “pass” even though the result is actually “fail”, will be described with reference to FIGS. 10 and 11.

FIG. 10 is a generation method of ΔVclk according to the comparative example. The clock VCLKx generation circuit shown in FIG. 10A generates the clock VCLKx represented by the expression of VCLKx=VBLC+10 uA×25 kΩ=VBLC+0.25V. When A attains “H” in the circuit of FIG. 10B, the clock VCLKx is transmitted to the clock node (VCLK). When B attains “L” in the circuit of FIG. 10C, the clock VCLK is transmitted to the clock node (CLK). At this moment, the threshold voltage of the NMOS transistor 89 of FIG. 10C is Vtn, and ΔVclk=VCLKx−Vtn=VBLC+0.25V−Vtn holds, and therefore ΔVclk is a value of about 1 V.

FIG. 11A shows a timing chart extracted from the timing chart of FIG. 8 to enlarge a portion from the times t2 to t5 of the potential of the sense node 42 (SEN) and the clock node 43 (CLK). FIG. 11B is a schematic diagram showing a distribution of the threshold voltage of the memory cell transistor after erase. FIG. 11B corresponds to three cases (SEN1 to SEN3) of time change of the potential at the sense node 42 (SEN) shown in FIG. 11A.

As shown by the distribution of SEN2 in FIG. 11B, a case will be considered where the maximum value of the threshold voltage distribution of the memory cell transistors after erase is larger than the reference value of the erase verification and is smaller than −Vdd. With the driver circuit shown in FIG. 4, the potential of the bit line BL is the absolute value of the maximum value of the threshold distribution of the memory cell transistors even in the distribution of SEN2. Accordingly, at the time t3, Vsenev+Vth is applied to the gate electrode of the transistor 34 (BLC), and even after the sense node 42 (SEN) is discharged to the BL potential, the bit line potential Vbl is the power supply voltage (Vdd) or more. Even when the sense node (SEN) is stepped down by the amplitude (ΔVclk to about 1 V) of the clock CLK 43 of the comparative example at the time t5, the potential of the sense node 42 (SEN) does not become the trip point or less. In other words, in the threshold voltage distribution of SEN2 of FIG. 11B, the determination result of the verification operation is determined to be “pass” in spite of the face that it is actually “fail”. This means that false reading has occurred.

It should be noted that ΔVclk can be increased to 1 V or more by making the resistive value of R2 larger to make the clock VCLKx larger in the circuit shown in FIG. 10A of the comparative example. However, the voltage represented by the clock VCLKx is also used by, for example, reading operation in addition to the erase verification operation. Therefore, the method of simply increasing the clock VCLKx may cause a problem in the reading operation.

As described above, according to the embodiment of the invention, (1) the reference value of the erase verification is set to a voltage lower than −Vdd, and (2) the value of ΔVclk is set to a value larger than that of the comparative example, so that a wider erase verification margin is ensured. Therefore, a deep erase can be achieved to alleviate the problems caused by the adjacency effects.

The present invention is not limited directly to the above described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined. It is to be understood that within the scope of the appended claims, the present invention may be practiced other than as specifically disclosed.

What is claimed is:

1. A non-volatile semiconductor memory device, comprising:
a memory cell array having a plurality of non-volatile memory cells capable electrically rewriting data, bit lines and source lines;
a driver circuit coupled with the source lines of the memory cell array, to output a voltage higher than a power source voltage or a programming voltage for writing data in a memory cell at an output terminal and discharge the source lines to ground by switching over; and
a sense amplifier circuit coupled with the bit line to read data in the memory cell, the sense amplifier circuit including a sense node and a capacitor having a first terminal coupled with the sense node and a second terminal to receive a plurality of voltages to boost the sense node.

2. The non-volatile semiconductor memory device according to claim 1, wherein the driver circuit including;
a transistor having a gate, a drain to receive a first higher voltage than a power source voltage and a source coupled with the output terminal, and
a level shifter having an output terminal coupled with the gate of the transistor, a first input terminal to receive a switch signal and a second input signal to receive a second higher voltage than the power source voltage from a high voltage supply circuit.

3. The non-volatile semiconductor memory device according to claim 1, wherein the plurality of voltages to boost the sense node is generated by a voltage generating circuit including;
a first resistor,
a second resistor coupled with the first resistor in series, and
a transistor having a gate and a source-drain path coupled in parallel with the second resister to form a detour route of the second resistor by an input signal applied to the gate.

4. The non-volatile semiconductor memory device according to claim 1, wherein a voltage to verify an erased state of a memory cell is higher than a voltage used to read out data.

5. A non-volatile semiconductor memory device, comprising:
a memory cell array including a plurality of NAND strings arranged in a matrix, each of the NAND strings having a plurality of non-volatile memory cells connected in series and capable electrically rewriting data, and first and second selection gate transistors coupled with both ends of the plurality of non-volatile memory cells;
source lines coupled with the first selection transistors of the NAND strings;
bit lines coupled with the second selection transistors of the NAND strings;
a source driver circuit coupled with the source line to supply a higher voltage than a power source voltage; and
a sense amplifier circuit coupled with the bit line to read data in the memory cell; and
wherein the sense amplifier circuit further includes sense node, a capacitor having a first terminal coupled with the sense node and a second terminal to receive a plurality of voltages to boost the sense node, and a first transistor connected between the sense node and the bit line of the memory cell array, and the first transistor is switched depending on the voltage of the bit line.

6. The non-volatile semiconductor memory device according to claim 5, wherein in an erase verify operation by flowing a current in the bit line through the NAND string from the source driver circuit, if all the memory cells of a NAND string are erased at a value below a predetermined verify standard voltage, the sense node maintains a voltage value boosted to a higher voltage than the power source voltage, and if the NAND string includes non-erased memory cells, the first transistor turns on, and the sense node is discharged up to the substantially same voltage as the bit line.

7. The non-volatile semiconductor memory device according to claim 6, wherein in the erase verify operation, the voltages of the respective word lines coupled the memory cells in the selected NAND string are set at 0 volt, and the gate voltages of the first and second selection transistors are set to the power source voltage.

8. The non-volatile semiconductor memory device according to claim 6, wherein the sense amplifier circuit includes a second transistor coupled with the sense node to charge the sense node.

9. The non-volatile semiconductor memory device according to claim 8, wherein the erase verify operation is done, first, by charging the sense node to the power source voltage by conducting the second transistor, then shutting the charging route by non-conducting the second transistor, and boosting the sense node to a higher voltage than the power source voltage by a clock signal applied to the capacitor.

10. The non-volatile semiconductor memory device according to claim 9, wherein the sense amplifier circuit includes a third transistor having a source coupled with the power source, a gate coupled with the sense node and a drain, and the third transistor is switched by the result of the erase verify operation.

11. The non-volatile semiconductor memory device according to claim 10, wherein the sense amplifier circuit includes a latch circuit coupled with the drain electrode of the third transistor.

12. The non-volatile semiconductor memory device according to claim 5, wherein the plurality of voltages to boost the sense node is generated by a voltage generating circuit including;
a first resistor,
a second resistor coupled with the first resistor in series,
a fourth transistor having a gate and a source-drain path coupled in parallel with the second resister to form a detour route by an input signal applied to the gate.

13. The non-volatile semiconductor memory device according to claim 12, wherein the voltage generating circuit outputs either one of the first voltage corresponding to the first resistor or the second voltage corresponding to the first and second resistors connected in series.

14. The non-volatile semiconductor memory device according to claim 5, wherein the source driver circuit includes a level shifter and outputs either one of the output signal of the level shifter or a voltage used to write data in the memory cell by switching, and discharges the source line to ground.

15. The non-volatile semiconductor memory device according to claim 14,
wherein the source driver circuit includes a fifth transistor having a gate and a drain to receive a higher voltage than the power source voltage and a source coupled with the output terminal of the source driver circuit, and the level shifter includes a first input terminal to receive a switch signal, a second input signal to receive a higher voltage than the power source voltage from a high voltage supply circuit and an output terminal coupled with the gate of the fifth transistor.
